(19) United States
(12) Patent Application Publication
(10) Pub. No.: US 2014/0312771 A1
(43) Pub. Date: Oct. 23, 2014

(54) RECTANGULAR LED LIGHTING APPARATUS

(71) Applicant: POSCO LED COMPANY LTD., Seongnam-si (KR)

(72) Inventors: Deok Ju LEE, Seongnam-si (KR); Dae Won Kim, Seongnam-si (KR); Seong Bok Yoon, Seongnam-si (KR); II Park, Seongnam-si (KR)

(21) Appl. No.: 13/907,208

(22) Filed: May 31, 2013

(30) Foreign Application Priority Data
Apr. 17, 2013 (KR) 10-2013-0042102

(51) Int. Cl. H05B 33/08; H05K 7/20

(52) U.S. Cl. CPC H05B 33/0803; H05K 7/205
USPC 315/113; 315/312

(57) ABSTRACT

A rectangular LED lighting apparatus connected directly to an AC power supply is provided. The rectangular LED lighting apparatus includes: a printed circuit board in which circuit patterns are formed for electrical connection of LEDs; a rectification unit configured to rectify an AC voltage and output a DC rectified voltage; an LED unit driven by the rectified voltage, the LED unit including first to n-th light emitting blocks (where n is a positive integer equal to or greater than 2) arranged linearly on the printed circuit board; and an LED driving control unit configured to sequentially drive first to m-th light emitting groups (where m is a positive integer equal to or greater than 2), each of which includes n LEDs, according to a voltage level of the rectified voltage output from the rectification unit.

### CROSS-REFERENCE TO RELATED APPLICATION

This application claims priority from and the benefit of Korean Patent Application No. 10-2013-0042102, filed on Apr. 17, 2013, which is hereby incorporated by reference for all purposes as if fully set forth herein.

### BACKGROUND OF THE INVENTION

1. Field of the Invention

The present invention relates to a rectangular LED lighting apparatus, and more particularly, to a rectangular LED lighting apparatus, in which the arrangement and connection relationship of a plurality of LEDs included in a plurality of light emitting blocks sequentially driven in an AC LED lighting apparatus are optimized for configuring a rectangular AC LED lighting apparatus.

2. Discussion of the Background

A light emitting diode (LED) is a semiconductor element that is made of a material such as gallium (Ga), phosphorus (P), arsenic (As), indium (In), nitrogen (N), and aluminum (Al). The LED has a diode characteristic and emits red light, green light, or blue light when a current flows therethrough. Compared with a bulb or lamp, the LED has a long lifespan, a fast response speed (time until light is emitted after a current flows), and low power consumption. Due to these advantages, the LED has tended to be widely used.

In general, a light emitting device could be driven only with a DC voltage due to the characteristic of the diode characteristic. Therefore, a light emitting device using a conventional light emitting element is restrictive in use and must include a separate circuit, such as SMPS, so as to use an AC voltage that has been currently used at home. Consequently, the circuit of the light emitting device becomes complicated and the manufacturing cost of the light emitting device increases.

In order to solve these problems, much research has been conducted on a light emitting element that can also be driven with an AC voltage by connecting a plurality of light emitting cells in series or in parallel.

FIG. 1 is a block diagram illustrating a configuration of a conventional AC LED lighting apparatus, and FIG. 2 is a waveform diagram illustrating waveforms of a rectified voltage and an LED driving current in the conventional AC LED lighting apparatus of FIG. 1.

As illustrated in FIG. 1, the conventional AC LED lighting apparatus includes an AC power supply V_{AC}, a rectification unit 10, a first light emitting group 20, a second light emitting group 22, a third light emitting group 24, a fourth light emitting group 26, a driving control unit 40, a first light emitting group driving unit (first switch) SW1, a second light emitting group driving unit (second switch) SW2, a third light emitting group driving unit (third switch) SW3, and a fourth light emitting group driving unit (fourth switch) SW4. Specifically, the rectification unit 10 receives an AC voltage from the AC power supply V_{AC} and performs a full-wave rectification on the AC voltage to output a rectified voltage V_{rec}. The first light emitting group 20, the second light emitting group 22, the third light emitting group 24, and the fourth light emitting group 26 receive the rectified voltage V_{rec} and are sequentially driven. The driving control unit 40 controls the sequential driving of the first light emitting group 20, the second light emitting group 22, the third light emitting group 24, and the fourth light emitting group 26 according to a voltage level of the rectified voltage V_{rec}. The first light emitting group driving unit SW1, the second light emitting group driving unit SW2, the third light emitting group driving unit SW3, and the fourth light emitting group driving unit SW4 have a switching function and a constant current control function.

A process of driving the conventional AC LED lighting apparatus will be described below with reference to FIG. 2. The driving control unit 40 determines the voltage level of the rectified voltage V_{rec} applied from the rectification unit 10, and sequentially drives the first light emitting group 20, the second light emitting group 22, the third light emitting group 24, and the fourth light emitting group 26 according to the determined voltage level of the rectified voltage V_{rec}.

Accordingly, in periods during which the voltage level of the rectified voltage V_{rec} is equal to or higher than a first threshold voltage V_{TH1} and lower than a second threshold voltage V_{TH2} (t1 to t2 and t7 to t8 in one cycle of the rectified voltage V_{rec}), the driving control unit 40 maintains the first switch SW1 in a turned-on state and maintains the second switch SW2, the third switch SW3, and the fourth switch SW4 in a turned-off state, so that only the first light emitting group 20 is driven.

In addition, in periods during which the voltage level of the rectified voltage V_{rec} is equal to or higher than the second threshold voltage V_{TH2} and lower than a third threshold voltage V_{TH3} (t2 to t3 and t6 to t7 in one cycle of the rectified voltage V_{rec}), the driving control unit 40 maintains the second switch SW2 in a turned-on state and maintains the first switch SW1, the third switch SW3, and the fourth switch SW4 in a turned-off state, so that only the first light emitting group 20 and the second light emitting group 22 are driven.

In addition, in periods during which the voltage level of the rectified voltage V_{rec} is equal to or higher than the third threshold voltage V_{TH3} and lower than a fourth threshold voltage V_{TH4} (t3 to t4 and t5 to t6 in one cycle of the rectified voltage V_{rec}), the driving control unit 40 maintains the third switch SW3 in a turned-on state and maintains the first switch SW1, the second switch SW2, and the fourth switch SW4 in a turned-off state, so that the first light emitting group 20, the second light emitting group 22, and the third light emitting group 24 are driven.

In addition, in periods during which the voltage level of the rectified voltage V_{rec} is equal to or higher than the fourth threshold voltage V_{TH4} (t4 to t5 in one cycle of the rectified voltage V_{rec}), the driving control unit 40 maintains the fourth switch SW4 in a turned-on state and maintains the first switch SW1, the second switch SW2, and the third switch SW3 in a turned-off state, so that all of the first light emitting group 20, the second light emitting group 22, the third light emitting group 24, and the fourth light emitting group 26 are driven.

Meanwhile, in the case of the conventional AC LED lighting apparatus as illustrated in FIG. 1, the first light emitting group 20, the second light emitting group 22, the third light emitting group 24, and the fourth light emitting group 26 are connected in series and are sequentially turned on and off. Therefore, when a rectangular LED lighting apparatus is configured using the conventional AC LED lighting apparatus, there has been a problem in light uniformity of the LED lighting apparatus. That is, in a case where the first light emitting group 20, the second light emitting group 22, the third light emitting group 24, and the fourth light emitting group 26 are disposed and mounted sequentially from left to right on a substrate of the rectangular LED lighting apparatus, if the voltage level of the rectified voltage V_{rec} is low, for example, in periods during which the voltage level of the rectified voltage V_{rec} is equal to or higher than the first threshold voltage V_{TH1} and lower than the second threshold voltage V_{TH2} (t1 to t2 and t7 to t8 in one cycle of the rectified voltage V_{rec}), only the first light emitting group 20 disposed on the leftmost side of the rectangular LED lighting apparatus emits light. As a result, the rectangular LED lighting apparatus may not perform its own inherent function as the lighting apparatus. Therefore, in order to implement the rectangular LED lighting apparatus by using the AC LED lighting apparatus operating based on a sequential driving mode, there is a need for new arrangement and connection structure of a plurality of LEDs included in a plurality of light emitting groups. However, specific solutions to such problems have not been proposed.

### SUMMARY OF THE INVENTION

The present invention has been made in an effort to solve the above-described problems of the related art.

The present invention is directed to provide a rectangular LED lighting apparatus including a plurality of light emitting groups each of which is sequentially driven, which can obtain maximum luminous efficiency and excellent light uniformity through improved arrangement and connection structure of a plurality of LEDs included in the plurality of light emitting groups.

In addition, the present invention is directed to provide a rectangular LED lighting apparatus that can efficiently solve a heat dissipation problem caused by the improved arrangement and connection structure of the plurality of LEDs included therein.

Moreover, the present invention is directed to provide a rectangular LED lighting apparatus that can efficiently solve a breakdown voltage problem caused by the improved arrangement and connection structure of the plurality of LEDs included therein.

The characteristic configurations of the present invention for achieving the above objects of the present invention and achieving unique effects of the present invention are as follows.

According to an aspect of the present invention, a rectangular LED lighting apparatus includes: a printed circuit board in which circuit patterns are formed for electrical connection of LEDs; a rectification unit configured to rectify an AC voltage and output a DC rectified voltage; an LED unit driven by the rectified voltage, the LED unit including first to n-th light emitting blocks (where n is a positive integer equal to or greater than 2) arranged linearly on the printed circuit board; and an LED driving control unit configured to sequentially drive first to m-th light emitting groups (where m is a positive integer equal to or greater than 2), each of which includes n LEDs, according to a voltage level of the rectified voltage output from the rectification unit, wherein each of the first to n-th light emitting blocks includes first to m-th LEDs arranged linearly, and each of the first to m-th LEDs is sequentially turned on and off according to the voltage level of the rectified voltage.

The printed circuit board may be a printed circuit board having a horizontal length longer than a vertical length. The first to n-th light emitting blocks may be sequentially arranged on the printed circuit board in a horizontal direction. The first to m-th LEDs may be sequentially arranged on the printed circuit board in a horizontal direction within the light emitting block.

The printed circuit board may include: a first conductive circuit pattern formed on a top surface of the printed circuit board; and a second conductive circuit pattern formed on a bottom surface of the printed circuit board.

The printed circuit board may include a through-hole passing through top and bottom surfaces, and the through-hole includes a heat conductive member inside.

The printed circuit board may further include a first heat sink pattern formed on the bottom surface thereof and connected to the heat conductive member.

The printed circuit board may further include a second heat sink pattern formed on the top surface thereof and connected to the heat conductive member.

The LED may contact the second heat sink pattern.

The heat conductive member may be a metal pattern formed along an inner surface of the through-hole.

The first heat sink pattern may be made of a metal.

The second heat sink pattern may be made of a metal.

The inside of the through-hole may be filled with a heat conductive resin.

The rectangular LED lighting apparatus may further include: a heat sink; and an insulating heat sink member interposed between the printed circuit board and the heat sink.

The insulating heat sink member may include: an insulating base film; and a heat conductive adhesive coated on both sides of the base film.

The rectangular LED lighting apparatus may further include a release prevention member configured to prevent the printed circuit board from being released from the heat sink.

The release prevention member may be a hook with a latch protrusion, and the heat sink includes a coupling groove coupled to the latch protrusion of the hook.

The rectangular LED lighting apparatus may further include an optical member configured to diffuse light emitted from the plurality of LEDs.

A ratio of a gap between the plurality of LEDs and the optical member to a pitch of the light emitting block may be in a range from 1.2 to 0.8.

### BRIEF DESCRIPTION OF THE DRAWINGS

The accompanying drawings, which are included to provide a further understanding of the invention and are incorporated in and constitute a part of this specification, illustrate embodiments of the invention, and together with the description serve to explain the principles of the invention.

FIG. 1 is a block diagram illustrating a configuration of a conventional AC LED lighting apparatus.

FIG. 2 is a waveform diagram illustrating waveforms of a rectified voltage and an LED driving current in the conventional AC LED lighting apparatus of FIG. 1.

FIG. 3 is a block diagram illustrating a configuration of a rectangular LED lighting apparatus according to an exemplary embodiment of the present invention.

FIG. 4 is a side perspective view schematically illustrating a rectangular LED lighting apparatus according to an embodiment of the present invention.

FIG. 5 is a plan view when viewed from above the rectangular LED lighting apparatus of FIG. 4.

FIG. 6 is a side perspective view illustrating a rectangular LED lighting apparatus according to another embodiment of the present invention.

FIG. 7 is a cross-sectional view illustrating the rectangular LED lighting apparatus of FIG. 6.

FIG. 8 is a cross-sectional view illustrating a rectangular LED lighting apparatus according to yet another embodiment of the present invention.

FIG. 9 is a cross-sectional view illustrating a rectangular LED lighting apparatus according to still another embodiment of the present invention.

FIG. 10 is a plan view illustrating the rectangular LED lighting apparatus according to the embodiment of the present invention, which further includes a hook as a release prevention member.

FIG. 11 is a cross-sectional view illustrating the rectangular LED lighting apparatus according to the embodiment of the present invention, which further includes a hook as a release prevention member.

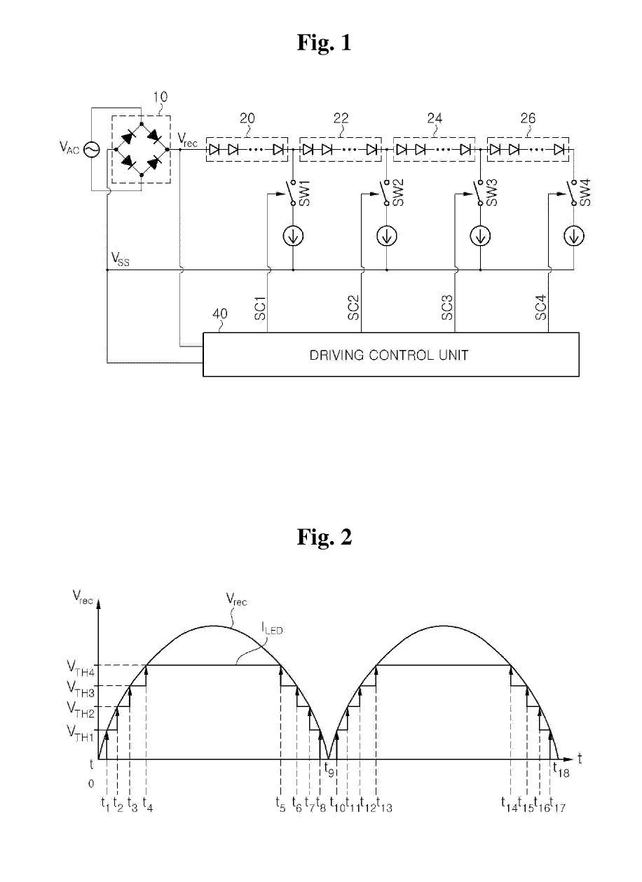

### DETAILED DESCRIPTION OF THE ILLUSTRATED EMBODIMENTS

Specific embodiments of the present invention will be described below in detail with reference to the accompanying drawings. These embodiments will be fully described in such a manner that those skilled in the art can easily carry out the present invention. It should be understood that various embodiments of the present invention are different from one another, but need not be mutually exclusive. For example, specific shapes, structures and characteristics described herein can be implemented in other embodiments, without departing from the spirit and scope of the present invention. In addition, it should be understood that the positions and arrangements of the individual elements within the disclosed embodiments can be modified without departing from the spirit and scope of the present invention. Therefore, the following detailed description is not intended to be restrictive. If appropriately described, the scope of the present invention is limited only by the accompanying claims and the equivalents thereof. Throughout the drawings, similar reference numerals refer to same or similar functions in various aspects.

Hereinafter, preferred embodiments of the present invention will be described in detail with reference to the accompanying drawings, such that those skilled in the art can easily carry out the present invention.

### Exemplary Embodiment of the Present Invention

In the embodiments of the present invention, the term “light emitting group” refers to a group of LEDs (LED packages) connected in series, in parallel, or in series/parallel to emit light within a lighting apparatus, and refers to a group of LEDs whose operations are controlled as one unit (that is, turned on/off at the same time) under the control of a control unit.

Also, the term “threshold voltage level V_{TH}” refers to a voltage level that can drive a single light emitting group. The term “first threshold voltage level V_{TH1}” is a voltage level that can drive a first light emitting group, and the term “second threshold voltage level V_{TH2}” is a voltage level that can drive a first light emitting group and a second light emitting group. When the threshold voltage level of the first light emitting group and the threshold voltage level of the second light emitting group are equal to each other, the second threshold voltage level V_{TH2} is 2V_{TH1}. Therefore, in the following, the term “n-th threshold voltage level V_{THn}” refers to a voltage level that can drive all of the first to n-th light emitting groups.

In addition, the term “sequential driving mode” refers to a mode in which a plurality of light emitting groups are sequentially turned on and off according to a voltage level of a rectified voltage generated by full-wave rectifying an AC voltage.

In addition, the term “light emitting block” refers to a light emitting block in which LEDs belonging to each light emitting group sequentially driven are disposed adjacent to one another on a printed circuit board. For example, when first to fourth light emitting groups each including two LEDs are provided, the first light emitting block includes a (1-1)th LED belonging to the first light emitting group, a (2-1)th LED belonging to the second light emitting group, a (3-1)th LED belonging to the third light emitting block, and a (4-1)th LED belonging to the fourth light emitting group, all of which are arranged adjacent to one another on the printed circuit board. Similarly, the second light emitting block includes a (1-2)th LED belonging to the first light emitting group, a (2-2)th LED belonging to the second light emitting group, a (3-2)th LED belonging to the third light emitting block, and a (4-2)th LED belonging to the fourth light emitting group, all of which are arranged adjacent to one another on the printed circuit board.

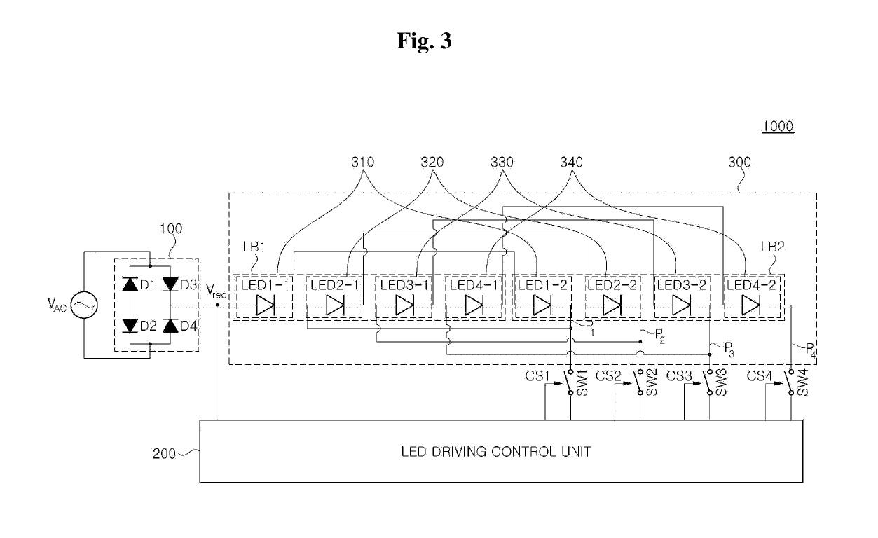

FIG. 3 is a block diagram illustrating a configuration of a rectangular LED lighting apparatus according to an exemplary embodiment of the present invention. Hereinafter, the configuration and function of the rectangular LED lighting apparatus 1000 according to the present invention will be described in detail with reference to FIG. 3.

As illustrated in FIG. 3, the rectangular LED lighting apparatus 1000 according to the present invention includes a rectification unit 100, an LED driving control unit 200, and an LED unit 300.

The rectification unit 100 may be configured to receive an AC voltage V_{AC} from an AC power supply disposed inside or outside the rectangular LED lighting apparatus 1000, rectify the received AC voltage V_{AC}, and output a rectified voltage V_{rec}. As described above, the rectangular LED lighting apparatus cannot be provided with a constant current/constant voltage circuit, such as SMPS, due to its characteristic. Therefore, the rectification unit 100 according to the present invention can be implemented with a half-wave rectification circuit or a full-wave rectification circuit constituted by a full-bridge. In FIG. 3, a full-wave rectification circuit constituted by four diodes D1, D2, D3 and D4 is illustrated. In addition, although not illustrated, the rectification unit 100 according to the present invention may further include a surge protection unit (not illustrated) and a fuse unit (not illustrated). The surge protection unit may be implemented with a varistor or the like that can protect a circuit from a surge voltage, and the fuse unit may be implemented with a fuse or the like that can protect a circuit from overcurrent.

The LED unit 300 according to the present invention receives the rectified voltage V_{rec} applied from the rectification unit 100 and emits light. Various types of the LED unit 300 may be used for the rectangular LED lighting apparatus 1000 according to the present invention. More specifically, the LED unit 300 according to the present invention may include m light emitting groups, each of which is configured with n LEDs. Herein, n and m are positive integers and, if necessary, n and m may be variously set. In the case of the embodiment illustrated in FIG. 3, for convenience of description and understanding, it is assumed that the LED unit 300 is configured with the first to fourth light emitting groups 310 to 340, each of which includes two LEDs. However, the present invention is not limited to the above configuration, and it is obvious to those skilled in the art that various modifications and changes can be made without departing from the scope of the present invention, and such modifications and changes fall within the scope of the present invention.

As described above, the LED unit 300 according to the present invention is configured to have improved arrangement and connection structure among the LEDs in order for the constitution of the rectangular LED lighting apparatus 1000. For this purpose, the LEDs within the LED unit 300 according to the present invention are configured such that the respective LEDs belonging to the four light emitting groups are sequentially arranged one by one in order of the light emitting groups to constitute the plurality of light emitting blocks. Specifically, as illustrated in FIG. 3, the (1-1)th LED LED1-1 belonging to the first light emitting group 310 is arranged on the leftmost side; the (2-1)th LED LED2-1 belonging to the second light emitting group 320 is arranged behind the (1-1)th LED LED1-1; the (3-1)th LED LED3-1 belonging to the third light emitting group 330 is arranged behind the (2-1)th LED LED2-1; and the (4-1)th LED LED4-1 belonging to the fourth light emitting group 340 is arranged behind the (3-1)th LED LED3-1. In this manner, the first light emitting block LB1 is constituted. Similarly, the (1-2)th LED LED1-2 belonging to the first light emitting group 310 is arranged behind the (4-1)th LED LED4-1; the (2-2)th LED LED2-2 belonging to the second light emitting group 320 is arranged behind the (1-2)th LED LED1-2; the (3-2)th LED LED3-2 belonging to the third light emitting group 330 is arranged behind the (2-2)th LED LED2-2; and the (4-2)th LED LED4-2 belonging to the fourth light emitting group 340 is arranged behind the (3-2)th LED LED3-2. In this manner, the second light emitting block LB2 is constituted. That is, each of the light emitting blocks LB1 and LB2 includes a single LED belonging to the first light emitting group 310, a single LED belonging to the second light emitting group 320, a single LED belonging to the third light emitting group 330, and a single LED belonging to the fourth light emitting group 340. A plurality of light emitting blocks constituted in such a manner are sequentially arranged to configure the LED unit 300. For exemplary purposes, the description has been made based on the embodiment in which a single LED among LEDs belonging to each light emitting group is included in a single light emitting block, but the present invention is not limited thereto. It is obvious to those skilled in the art that a plurality of LEDs among LEDs belonging to each light emitting group can be included in a single light emitting block. Therefore, in a case where the LED unit 300 according to the present invention is configured with m light emitting groups each including n LEDs, the first to n-th light emitting blocks LB1 to LBN each including m LEDs are sequentially arranged and mounted on a printed circuit board (PCB). Therefore, the first light emitting block LB1 includes m LEDs, that is, the (1-1)th LED LED1-1 to the (m-1)th LED LEDm-1 arranged linearly. Similarly, the second light emitting block LB2 disposed next to the first light emitting block LB1 includes m LEDs, that is, the (1-2)th LED LED1-2 to the (m-2)th LED LEDm-2 arranged linearly. In addition, the j-th light emitting block LBj (where, j is a positive integer equal to or less than n) includes m LEDs, that is, the (1-j)th LED LED1-j to the (m-j)th LED LEDm-j arranged linearly In addition, similarly, the n-th light emitting block LBN, the last light emitting block, includes m LEDs, that is, the (1-n)th LED LED1-n to the (m-n)th LED LEDm-n arranged linearly Hereinafter, the (i-j)th LED LEDi-j refers to an LED that is arranged to belong to the j-th light emitting block LBj on the PCB and simultaneously belong to the i-th light emitting group, so that the LED is turned on when the LED driving control unit 200 turns on the i-th light emitting group and is turned off when the LED driving control unit 200 turns off the i-th light emitting group. As described above, the LED unit 300 according to the present invention can be variously modified according to the number of the light emitting groups constituting the LED unit 300 and the number of the LEDs constituting the light emitting group. It should be noted that the technical essentials of the present invention are to configure the rectangular LED lighting apparatus 1000 such that each of the plurality of light emitting blocks sequentially arranged to constitute the rectangular LED lighting apparatus 1000 is configured to include at least one LED belonging to each of the plurality of light emitting groups sequentially driven according to the voltage level of the rectified voltage V_{rec}, ensuring the light uniformity of the rectangular LED lighting apparatus 1000 regardless of the voltage level of the rectified voltage V_{rec}. Hereinafter, for convenience of description and understanding, the operation of the rectangular LED lighting apparatus 1000 according to the present invention will be described based on the embodiment of FIG. 3 in which the rectangular LED lighting apparatus includes the first to fourth light emitting groups configured to be sequentially driven, and the LEDs are arranged in the and second light emitting blocks LB1 and LB2. In addition, it is assumed that all of the first to fourth light emitting groups have the same threshold voltage.

The LED driving control unit 200 according to the present invention determines the voltage level of the rectified voltage V_{rec} applied from the rectification unit 100, generates a first switch control signal CS1, a second switch control signal CS2, a third switch control signal CS3, and a fourth switch control signal CS4 according to the determined voltage level of the rectified voltage V_{rec}, and sequentially drives the first light emitting group 310, the second light emitting group 320, the third light emitting group 330, and the fourth light emitting group 340 by controlling the first switch SW1, the second switch SW2, the third switch SW3, and the fourth switch SW4 according to the first to fourth control signals CS1 to CS4. Meanwhile, the first switch SW1, the second switch SW2, the third switch SW3, and the fourth switch SW4 may be implemented using one of a metal-oxide semiconductor field effect transistor (MOSFET), an insulated gate bipolar transistor (IGBT), a bipolar junction transistor (BJT), a junction field effect transistor (JFET), a thyristor (silicon controlled rectifier), and a triac, which can be turned on or off according to the switch control signals input from the LED driving control unit 200. Furthermore, the first switch SW1, the second switch SW2, the third switch SW3, and the fourth switch SW4 according to the present invention may be configured to perform a constant current control such that the current flows through the switches with a preset constant current value under the control of the LED driving control unit 200.

Hereinafter, the process of driving the rectangular LED lighting apparatus 1000 according to the present invention, based on one cycle of the rectified voltage V_{rec} illustrated in FIG. 2, will be described in more detail.

When the voltage level of the rectified voltage V_{rec} gradually rises from 0 V and reaches the first threshold voltage V_{TH1} (time point t1), the LED driving control unit 200 forms a first current path P1 by turning on the first switch SW1 and maintaining the second to fourth switches SW2 to SW4 in the turned-off state. Therefore, the (1-1)th LED LED1-1 of the first light emitting block LB1 and the (1-2)th LED LED1-2 of the second light emitting block LB2 emit light.

Subsequently, when the voltage level of the rectified voltage V_{rec} further rises and reaches the second threshold voltage V_{TH2} (time point t2), the LED driving control unit 200 forms a second current path P2 by turning off the first switch SW1, turning on the second switch SW2, and maintaining the third and fourth switches SW3 and SW4 in the turned-off state. Therefore, the (1-1)th LED LED1-1 and the (2-1)th LED LED2-1 of the first light emitting block LB1 and the (1-2)th LED LED1-2 and the (2-2)th LED LED2-2 of the second light emitting block LB2 emit light.

Subsequently, when the voltage level of the rectified voltage V_{rec} further rises and reaches the third threshold voltage V_{TH3} (time point t3), the LED driving control unit 200 forms a third current path P3 by turning off the second switch SW2, turning on the third switch SW3, and maintaining the first and fourth switches SW1 and SW4 in the turned-off state. Therefore, the (1-1)th LED LED1-1, the (2-1)th LED LED2-1, and the (3-1)th LED LED3-1 of the first light emitting block LB1 and the (1-2)th LED LED1-2, the (2-2)th LED LED2-2, and the (3-2)th LED LED3-2 of the second light emitting block LB2 emit light.

In addition, when the voltage level of the rectified voltage V_{rec} further rises and reaches the fourth threshold voltage V_{TH4} (time point t4), the LED driving control unit 200 forms a fourth current path P4 by turning off the third switch SW3, turning on the fourth switch SW4, and maintaining the first and second switches SW1 and SW2 in the turned-off state. Therefore, the (1-1)th LED LED1-1, the (2-1)th LED LED2-1, the (3-1)th LED LED3-1, and the (4-1)th LED LED4-1 of the first light emitting block LB1 and the (1-2)th LED LED1-2, the (2-2)th LED LED2-2, the (3-2)th LED LED3-2, and the (4-2)th LED LED4-2 of the second light emitting block LB2 emit light.

Meanwhile, when the voltage level of the rectified voltage V_{rec} reaches the maximum level and then falls below the fourth threshold voltage V_{TH4} (time point t5), the LED driving control unit 200 forms the third current path P3 by turning off the fourth switch SW4, turning on the third switch SW3, and maintaining the first and second switches SW1 and SW2 in the turned-off state. Therefore, the (1-1)th LED LED1-1, the (2-1)th LED LED2-1, and the (3-1)th LED LED3-1 of the first light emitting block LB1 and the (1-2)th LED LED1-2, the (2-2)th LED LED2-2, and the (3-2)th LED LED3-2 of the second light emitting block LB2 emit light.

Subsequently, when the voltage level of the rectified voltage V_{rec} falls below the third threshold voltage V_{TH3} (time point t6), the LED driving control unit 200 forms the second current path P2 by turning off the third switch SW3, turning on the second switch SW2, and maintaining the first and fourth switches SW1 and SW4 in the turned-off state. Therefore, the (1-1)th LED LED1-1 and the (2-1)th LED LED2-1 of the first light emitting block LB1 and the (1-2)th LED LED1-2 and the (2-2)th LED LED2-2 of the second light emitting block LB2 emit light.

Subsequently, when the voltage level of the rectified voltage V_{rec} falls below the second threshold voltage V_{TH2} (time point t7), the LED driving control unit 200 forms the first current path P1 by turning off the second switch SW2, turning on the first switch SW1, and maintaining the third and fourth switches SW3 and SW4 in the turned-off state. Therefore, the (1-1)th LED LED1-1 of the first light emitting block LB1 and the (1-2)th LED LED1-2 of the second light emitting block LB2 emit light.

As described above, since the rectangular LED lighting apparatus 1000 according to the present invention is configured such that the plurality of light emitting blocks LB 1 to LBN arranged linearly can emit light at least partially according to the voltage level of the rectified voltage V_{rec}, the light uniformity of the rectangular LED lighting apparatus 1000 can be improved.

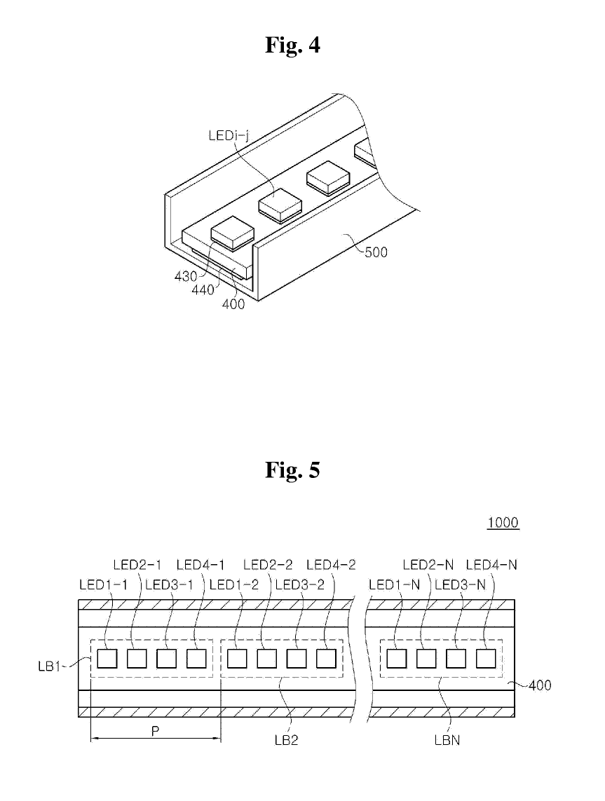

FIG. 4 is a side perspective view schematically illustrating the rectangular LED lighting apparatus 1000 according to the embodiment of the present invention, and FIG. 5 is a plan view when viewed from above the rectangular LED lighting apparatus 1000 of FIG. 4. The plurality of light emitting blocks L1, LB2, . . . , LBN and the PCB 400 configured and arranged as described above are illustrated in FIGS. 4 and 5.

Referring to FIGS. 4 and 5, as described above, circuit patterns for electrical connection of the LEDs are formed on the PCB 400, and the plurality of light emitting blocks LB1, LB2, . . . , LBN are sequentially arranged and mounted on the PCB 400 along the circuit patterns formed on the PCB 400. As described above, each of the light emitting blocks LB1, LB2, . . . , LBN may include four LEDs belonging to different light emitting groups. That is, as illustrated in FIG. 5, the first light emitting block LB1 includes four LEDs, that is, the (1-1)th LED LED1-1 to the (4-1)th LED LED4-1 arranged linearly. Similarly, the second light emitting block LB2 disposed next to the first light emitting block LB1 includes four LEDs, that is, the (1-2)th LED LED1-2 to the (4-2)th LED LED4-2 arranged linearly. In addition, similarly, the n-th light emitting block LBN, the last light emitting block, includes four LEDs, that is, the (1-n)th LED LED1-n to the (4-n)th LED LED4-n arranged linearly In FIGS. 3 to 5, a single light emitting block LB is illustrated as including four LEDs, respectively, belonging to the first light emitting group 310, the second light emitting group 320, the third light emitting group 330, and the fourth light emitting group 340, but the present invention is not limited thereto. The light emitting block LB may include different number of LEDs for each light emitting group. For example, the light emitting block LB may include two LEDs belonging to the first light emitting group 310, one LED belonging to the second light emitting group 320, one LED belonging to the third light emitting group 330, and one LED belonging to the fourth light emitting group 340. In any case, the number of LEDs included in each of the light emitting blocks LB1, LB2, . . . , LBN is equal in the light emitting blocks. Therefore, even when the turn-on/turn-off time of the first to fourth light emitting groups 310 to 340 is different, brightness of the light emitting blocks LB1, LB2, . . . , LBN can be maintained at almost an equal level.

Meanwhile, if necessary, various types of circuit boards may be adopted and used as the PCB 400 according to the present invention. However, as illustrated in FIG. 3, the rectangular LED lighting apparatus 1000 according to the present invention requires complicated circuit wirings among the LEDs. Therefore, it is more preferable to use a double-sided PCB 400, on the top and bottom surfaces of which circuit patterns are formed. On the other hand, the use of the double-sided PCB 400 may cause a problem in a heat dissipation function for discharging heat generated from the LEDs and may cause a problem in a breakdown voltage of the PCB 400. The configuration contrived for resolving these problems will be described below with reference to FIGS. 8 to 11.

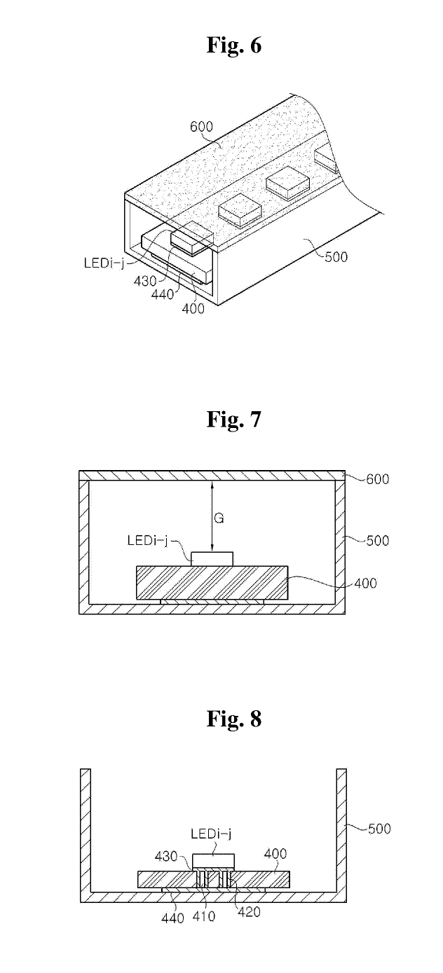

FIGS. 6 and 7 are a side perspective view and a cross-sectional view, respectively, illustrating a rectangular LED lighting apparatus 1000 according to another embodiment of the present invention. The embodiment illustrated in FIGS. 6 and 7 is an embodiment contrived for improving the light uniformity of the rectangular LED lighting apparatus 1000. The rectangular LED lighting apparatus 1000 illustrated in FIG. 6 further includes an optical member 600 in addition to the configuration of the rectangular LED lighting apparatus 1000 illustrated in FIG. 4.

The optical member 600 is spaced apart from the LED package by a predetermined distance and is coupled to the upper portion of the housing. The optical member 600 is made of a light-transmitting material such as polycarbonate or acryl. A light diffusion pattern, such as a prism pattern or a dot pattern, may be formed on at least one surface of the optical member 600. Unlike this, light may be diffused by coating beads having different particle sizes on the surface of the optical member 600. In addition, light may be diffused by forming air bubbles inside the optical member 600 such that light passing through the optical member 600 is scattered by the air bubbles inside the optical member 600.

According to the embodiment of FIGS. 6 and 7, the distribution of light irradiated from the rectangular LED lighting apparatus 1000 to the exterior can be made more uniformly by adjusting a gap G between the optical member 600 and the LED and a pitch P of one light emitting block (see FIG. 5). The pitch P of the light emitting block is a length occupied on a PCB by a specific light emitting block. For example, in FIG. 5, a distance from a start position of the first light emitting block LB1 (or a position at which the (1-1)th LED is disposed) to a start position of the second light emitting block LB2 (or a position at which the (1-2)th LED is disposed) becomes the pitch P of the light emitting block. As described above, the optical member 600 according to the present invention can perform a function of diffusing light emitted from the LEDs, but has a limitation in a diffusion angle. Therefore, by adjusting the pitch P of the light emitting block and the gap G between the optical member 600 and the LED, the rectangular LED lighting apparatus 1000 can be configured to output uniform light even in the period during which only one LED of the plurality of LEDs included in each light emitting block LB (that is, the period during which the voltage level of the rectified voltage V_{rec} is equal to or higher than the first threshold voltage V_{TH1} and lower than the second threshold voltage V_{TH2}). More specifically, a ratio of the gap G between the optical member 600 and the LED to the pitch P of the light emitting block may be in a range from 1.2 to 0.8. In addition, more preferably, the most uniform luminosity distribution can be obtained when the ratio of the gap G between the optical member 600 and the LED to the pitch P of the light emitting block is 0.8.

FIG. 8 is a cross-sectional view illustrating a rectangular LED lighting apparatus 1000 according to yet another embodiment of the present invention. The embodiment illustrated in FIG. 8 is an embodiment contrived for improving heat dissipation performance of the rectangular LED lighting apparatus 1000. The embodiment illustrated in FIG. 8 has the same configuration as the embodiment illustrated in FIG. 4, except for the configuration to be described below.

Terminals of an LED are electrically connected to a conductive pattern to be formed in a PCB 400. The PCB 400 includes a through-hole 410 passing through the top and bottom surfaces of the PCB 400. The PCB 400 is attached to a heat sink 500. In this case, the LED mounted on the PCB 400 is thermally connected to the heat sink 500 through the through-hole 410. The PCB 400 includes a first heat sink pad 440 and a second heat sink pad 430 formed on the top surface and the bottom surface of the PCB 400, respectively. The first heat sink pad 440 contacts the LED, and the second heat sink pad 430 contacts the heat sink 500. A heat sink passage made of a material with excellent heat conductivity is formed inside the through-hole 410. One end of the heat sink passage is connected to the first heat sink pad 440, and the other end of the heat sink passage is connected to the second heat sink pad 430. Heat generated from the LED is transferred to the heat sink 500 through the second heat sink pad 430, the heat sink passage, and the first heat sink pad 440. The heat sink 500 finally discharges the heat generated from the LED to the exterior.

The first heat sink pad 440, the second heat sink pad 430, and the heat sink passage may be made of a metal such as copper with high heat conductivity.

In the embodiment illustrated in FIG. 8, wiring patterns for electrical connection of LEDs, switching elements, other elements mounted on the PCB 400, and other elements outside the PCB 400 may be formed on at least one of the top and bottom surfaces of the PCB 400.

If the wiring patterns are formed on the bottom surface of the PCB 400, a gap between the wiring pattern formed on the bottom surface of the PCB 400 and the heat sink 500 is insufficient, causing a degradation in breakdown voltage characteristic. In order to compensate this problem, an insulating adhesive member may be interposed between the PCB 400 and the heat sink 500. In this case, the insulating adhesive member may be a double-sided tape having adhesive layers made of a material with excellent heat conductivity on two sides of a base film.

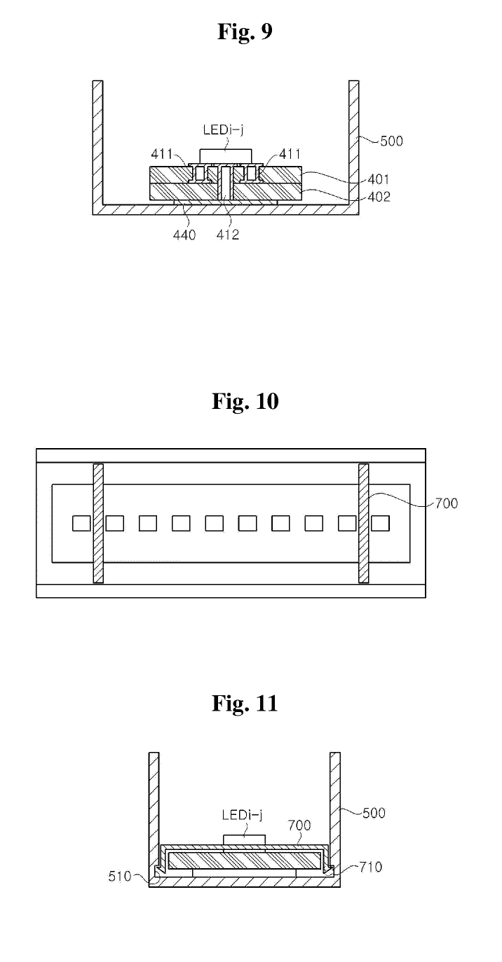

FIG. 9 is a cross-sectional view illustrating a rectangular LED lighting apparatus 1000 according to still another embodiment of the present invention. The rectangular LED lighting apparatus 1000 of FIG. 9 is substantially similar to the rectangular LED lighting apparatus of FIG. 8, except for features to be described below.

The PCB 400 includes a first insulating substrate 401, a second insulating substrate 402, a first wiring pattern formed on the top surface of the first insulating substrate 401, and a second wiring pattern formed between the first insulating substrate 401 and the second insulating substrate 402. LEDs, switching elements, other elements mounted on the PCB 400, and other elements outside the PCB 400 are electrically connected through the first wiring pattern and the second wiring pattern.

Since elements such as LEDs are mounted on the top surface of the first insulating substrate 401, interlayer wiring electrically connecting different layers is required for electrical connection of these elements and the second wiring pattern. The interlayer wiring is made through the first through-hole 411 passing through a first insulating substrate 401.

A first heat sink pad 440 is provided on the top surface of the first insulating substrate 401, and a second heat sink pad 430 is provided on the bottom surface of the second insulating substrate 402.

The first heat sink pad 440 and the second heat sink pad 430 are connected through a second through-hole 412.

The configuration and function of the first heat sink pad 440, the second heat sink pad 430, and the second through-hole 412 are substantially identical to those of the first heat sink pad 440, the second heat sink pad 430, and the through-hole 410 of the embodiment illustrated in FIG. 8.

In the embodiment of FIG. 9, when no wiring pattern is formed on the bottom surface of the second insulating substrate 402, all wiring patterns exist on the top surface of the first insulating substrate or a gap between the first insulating substrate 401 and the second insulating substrate 402. Therefore, higher breakdown voltage characteristic is ensured. As a result, in the embodiment of FIG. 9, a required breakdown voltage regulation can be satisfied even though a separate insulating member is not inserted between the PCB 400 and the heat sink 500.

In order to effectively discharge heat generated from the LED, it is necessary to firmly contact the PCB 400 with the heat sink 500. If the PCB 400 is released from the heat sink 500, the heat conduction efficiency between the PCB 400 and the heat sink 500 is lowered. In particular, if a separate insulating member is interposed between the PCB 400 and the heat sink 500, two or more adhesive layers for fixing exist. Therefore, the probability of release increases much more.

In order to solve this problem, the rectangular LED lighting apparatus 1000 according to the present invention may further include a release prevention member 700 for preventing the PCB 400 from being released from the heat sink 500. The release prevention member 700 may include a hook, one or more pairs of coupling protrusions and coupling grooves, a bolt and a nut, a rivet, or the like.

FIGS. 10 and 11 are a plan view and a cross-sectional view, respectively, illustrating a rectangular LED lighting apparatus 1000 according to an embodiment of the present invention, which further includes a hook as a release prevention member 700.

Referring to FIGS. 10 and 11, the heat sink 500 of the rectangular LED lighting apparatus 1000 according to the embodiment of the present invention includes a coupling groove 510 formed on an inner surface thereof. The PCB 400 is disposed on the heat sink 500, and a latch protrusion 710 of a hook is inserted into the coupling groove 510 formed in the heat sink 500. Therefore, it is possible to prevent the PCB 400 from being released from the heat sink 500.

In FIGS. 10 and 11, the configuration where the coupling groove into which the latch protrusion 710 of the hook is inserted is formed on a sidewall of the heat sink 500 is exemplarily illustrated, the coupling groove 510 may be formed on the top surface of the heat sink 500, or the like.

As described above, according to the present invention, the rectangular LED lighting apparatus can obtain maximum luminous efficiency and excellent light uniformity by using the improved arrangement and connection structure of the plurality of LEDs included in the plurality of light emitting groups that are sequentially driven.

In addition, according to the present invention, the heat dissipation problem caused by the improved arrangement and connection structure of the plurality of LEDs can be efficiently solved by forming the through-holes in the PCB and allowing heat generated from the LED package to be discharged through the through-holes to the exterior.

Furthermore, according to the present invention, the use of the insulating adhesive member including the breakdown voltage base can efficiently solve the breakdown voltage problem caused when the double-sided PCB is used for providing the improved arrangement and connection structure of the plurality of LEDs.

Moreover, according to the present invention, the use of the multilayer PCB can efficiently solve the breakdown voltage problem caused when the double-sided PCB is used for providing the improved arrangement and connection structure of the plurality of LEDs.

While the embodiments of the present invention have been described with reference to the specific embodiments, it will be apparent to those skilled in the art that various changes and modifications may be made without departing from the spirit and scope of the invention as defined in the following claims.

What is claimed is:

1. A rectangular light emitting diode (LED) lighting apparatus, comprising:
a printed circuit board in which circuit patterns are formed for electrical connection of LEDs;
a rectification unit configured to rectify an alternating current (AC) voltage and output a direct current (DC) rectified voltage;
an LED unit driven by the rectified voltage, the LED unit including first to n-th light emitting blocks, where n is a positive integer equal to or greater than 2, the first to n-th light emitting blocks arranged linearly on the printed circuit board; and
an LED driving control unit configured to sequentially drive first to m-th light emitting groups, where m is a positive integer equal to or greater than 2, each of which includes n LEDs, according to a voltage level of the rectified voltage output from the rectification unit,
wherein each of the first to n-th light emitting blocks includes first to m-th LEDs arranged linearly, and each of the first to m-th LEDs is sequentially turned on and off according to the voltage level of the rectified voltage.

2. The rectangular LED lighting apparatus of claim 1, wherein the printed circuit board is a printed circuit board having a horizontal length longer than a vertical length,
the first to n-th light emitting blocks are sequentially arranged on the printed circuit board in a horizontal direction, and
the first to m-th LEDs are sequentially arranged on the printed circuit board in a horizontal direction within the light emitting block.

3. The rectangular LED lighting apparatus of claim 1, wherein the printed circuit board comprises:
a first conductive circuit pattern formed on a top surface of the printed circuit board; and
a second conductive circuit pattern formed on a bottom surface of the printed circuit board.

4. The rectangular LED lighting apparatus of claim 1, wherein the printed circuit board includes a through-hole passing through top and bottom surfaces, and the through-hole includes a heat conductive member inside.

5. The rectangular LED lighting apparatus of claim 4, wherein the printed circuit board further comprises a first heat sink pattern formed on the bottom surface thereof and connected to the heat conductive member.

6. The rectangular LED lighting apparatus of claim 5, wherein the printed circuit board further comprises a second heat sink pattern formed on the top surface thereof and connected to the heat conductive member.

7. The rectangular LED lighting apparatus of claim 6, wherein the LED contacts the second heat sink pattern.

8. The rectangular LED lighting apparatus of claim 4, wherein the heat conductive member is a metal pattern formed along an inner surface of the through-hole.

9. The rectangular LED lighting apparatus of claim 5, wherein the first heat sink pattern is made of a metal.

10. The rectangular LED lighting apparatus of claim 6, wherein the second heat sink pattern is made of a metal.

11. The rectangular LED lighting apparatus of claim 4, wherein the inside of the through-hole is filled with a heat conductive resin.

12. The rectangular LED lighting apparatus of claim 3, further comprising:
a heat sink; and
an insulating heat sink member interposed between the printed circuit board and the heat sink.

13. The rectangular LED lighting apparatus of claim 12, wherein the insulating heat sink member comprises:
an insulating base film; and
a heat conductive adhesive coated on both sides of the base film.

14. The rectangular LED lighting apparatus of claim 13, further comprising a release prevention member configured to prevent the printed circuit board from being released from the heat sink.

15. The rectangular LED lighting apparatus of claim 14, wherein the release prevention member is a hook with a latch protrusion, and the heat sink includes a coupling groove coupled to the latch protrusion of the hook.

16. The rectangular LED lighting apparatus of claim 1, further comprising an optical member configured to diffuse light emitted from the plurality of LEDs.

17. The rectangular LED lighting apparatus of claim 16, wherein a ratio of a gap between the plurality of LEDs and the optical member to a pitch of the light emitting block is in a range from 1.2 to 0.8.
